(19) United States
(12) Patent Application Publication
(10) Pub. No.: US 2006/0214284 A1
(43) Pub. Date: Sep. 28, 2006

(54) Apparatus and method for data capture

(76) Inventors: Stuart Haden, Lucas, TX (US); Robert Skoog, Plano, TX (US); Christopher Freymuth, Fort collins, CO (US); Robert Wardwell, Colorado Springs, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/088,358

(22) Filed: Mar. 24, 2005

(51) Int. Cl. H01L 23/34

(52) U.S. Cl. 257/719

(57) ABSTRACT

Various data capture assemblies and methods are provided. In one embodiment, a data capture assembly is provided that includes a bolster plate with an aperture attached to a multi-chip module. A pad array is disposed on the multi-chip module and is exposed through the aperture. An interposer is electrically coupled to the pad array on the multi-chip module, and a translator board is electrically coupled to the interposer. A logical analyzer interface is electrically coupled to the translator board.

### BACKGROUND

Multi-chip modules may include many various integrated circuits such as microprocessor circuit and other circuits. Also, current multi-chip modules include thermal solutions in order to facilitate the running of many components. In order to test whether a particular multi-chip module is operational, pad arrays are provided that facilitate attachment of internal busses in a multi-chip module. However, as the amount of integrated circuits and other circuitry grows on given multi-chip modules, they become more complex, and the pad arrays employed for testing are being pushed to less important positions on the multi-chip modules. This presents a problem in that the pad arrays may not be as accessible for purposes of testing a multi-chip module.

### BRIEF DESCRIPTION OF THE SEVERAL VIEWS OF THE DRAWINGS

The invention can be understood with reference to the following drawings. The components in the drawings are not necessarily to scale. Also, in the drawings, like reference numerals designate corresponding parts throughout the several views.

FIG. 1 is a view of a multi-chip module in an inverted orientation according to an embodiment of the present invention;

FIG. 2 is an exploded view of a data capture assembly attached to the multi-chip module of FIG. 1 according to an embodiment of the present invention; and

FIG. 3 is a view of a bolster plate employed in the data capture assembly of FIG. 2 according to an embodiment of the present invention.

### DETAILED DESCRIPTION

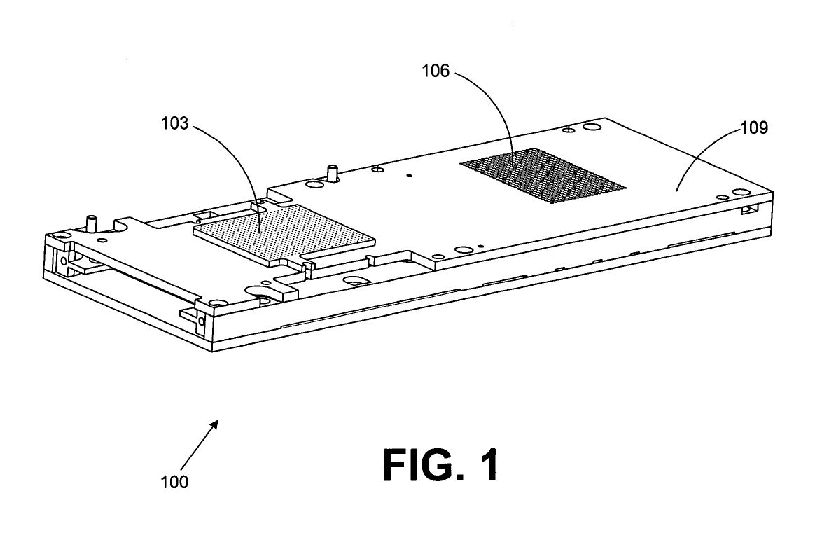

With reference to FIG. 1, shown is a multi-chip module 100 according to an embodiment of the present invention. The multi-chip module 100 is an assembly that includes a number of integrated circuits such as, for example, microprocessor circuits, power supplies, and other circuitry in a dense configuration. In addition, the multi-chip module 100 may include various thermal solutions (not shown) such as heat sinks and other such components. In one embodiment, the heat sinks are spring loaded and are compressed up against the integrated circuits from which heat is conducted so as to make good contact therewith for optimal heat transfer. Such thermal solutions may introduce various stresses to the printed circuit boards or other structures that make up the multi-chip module 100. Consequently, in some cases, bolster plates may be attached against the various printed circuit boards or other structures of the multi-chip module 100 to counteract the negative effects such as warping or other structural misshaping of the circuit boards due to such mechanical stress inducing components.

The integrated circuits, power supplies, thermal solutions, and other circuitry disposed in the various surfaces of the multi-chip module 100 present a dense arrangement in which an optimum is placed on the space available for circuitry in the multi-chip module 100. As such, it is undesirable to use room on the various circuit boards that make up the multi-chip module 100 for test points or test pad arrays from which signals may be accessed from the multi-chip module 100 in order for verification of proper operation after manufacturing is complete. This is because the function of verification of proper operation of the multi-chip module 100 is performed once to verify operation before the product is shipped to the end user. Consequently, it is undesirable to use valuable real estate on the surfaces of the various circuit boards of the multi-chip module 100 for test circuits and pad arrays that are not used during the normal operation. This is because such test circuits and pad arrays potentially displace circuitry that may be included to enhance the capabilities of the multi-chip module 100.

According to one embodiment, the multi-chip module 100 includes a pin array 103 and a pad array 106 disposed on a bottom surface 109 of the multi-chip module 100. The pin array 103 is employed to plug the multi-chip module 100 into, for example, a system board or other system as can be appreciated by those with ordinary skill in the art. The pad array 106 is employed to capture signals from various data busses within the multi-chip module 100 for testing purposes. The pin array 103 and the pad array 106 are advantageously located on the bottom surface 109 of the multi-chip module 100 which may then be placed against the surface of the system board or other board into which the pin array 103 is plugged. Also, various fastening systems may be employed to hold the multi-chip module 100 in place in such circumstances. Thus, the pad array 106 is advantageously placed on the bottom surface 109 of the multi-chip module 100 as it does not displace other circuitry or use up valuable real estate on the other surfaces of the multi-chip module 100 since the bottom surface 109 may not be employed for such circuitry.

However, given that the pad array 106 is located on the bottom surface 109 of the multi-chip module 100 along with the pin array 103, when the pin array 103 is plugged into a system board to facilitate the testing of the operation of the multi-chip module 100, there is little or no clearance to place a data capture assembly against the pad array 106 in order to capture data from the various data busses within the multi-chip module 100. To create clearance for a data capture assembly to attach or abut up against the pad array 106, a socket extender may be placed onto the pin array 103 to provide a gap within which the data capture assembly may properly fit. In this respect, the socket extender plugs into the pin array 103 and then into the respective system board. The clearance provided by the socket extender depends upon the thickness of the socket extender.

When the multi-chip module 100 is provided to end users, a solid bolster plate may be placed over the portion of the multi-chip module 100 where the pad array 106 is located so as to cover the pad array 106 to prevent shorting any of the contacts therein. Also, such a bolster plate counteracts the forces generated by various components such as components providing heat solution on the opposite side of the multi-chip module 100. When placed over the pad array 106, the bolster plate is insulated from the pad array 106 using an appropriate insulator to prevent shorting the electrical contacts of the pad array 106.

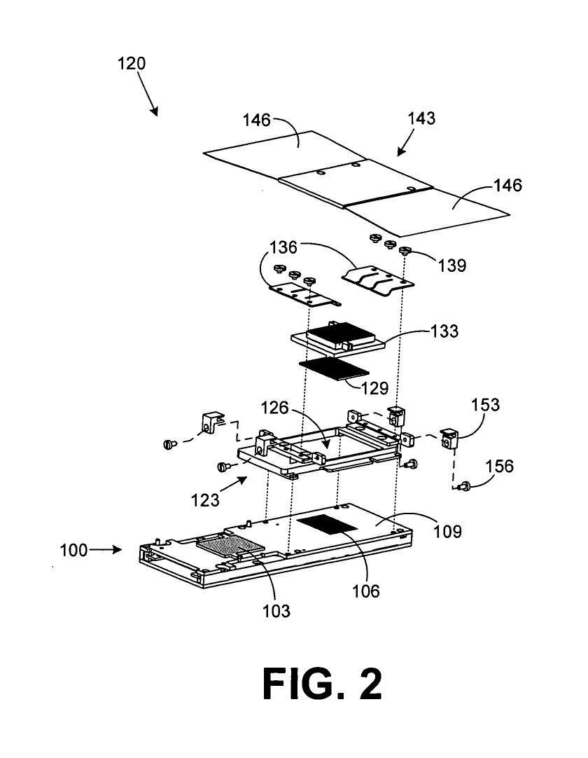

Turning then to FIG. 2, shown is a data capture assembly 120 according to an embodiment of the present invention. The data capture assembly 120 includes the multi-chip module 100. Attached to the multi-chip module 100 is a bolster plate 123. The bolster plate 123 includes an aperture 126. When the bolster plate 123 is placed onto the multi-chip module 100, the pad array 106 is exposed through the aperture 126. This allows other components to be mated with the pad array 106 as will be described.

In particular, the data capture assembly 120 also includes an interposer 129 and a translator board 133. Also, the data capture assembly 120 includes springs 136 that are fastened to the bolster plate 123 by virtue of screws 139. The data capture assembly 120 further includes a logical analyzer interface 143. The logical analyzer interface 143 includes a socket (not shown) on the underside that mates with a pin array of the translator board 133. Also, the logical analyzer interface 143 includes tabs 146 upon which signals are routed from the socket (not shown) of the logical analyzer interface 143 and to a logical analyzer as desired. The data that is captured through the logical analyzer interface 143 is provided to the logical analyzer that may store the data for various diagnostic tests, etc.

As stated above, the bolster plate 123 is attached to the multi-chip module 100 using screws or other fasteners. It is fastened in such a manner that the pad array 106 is exposed through the aperture 126 of the bolster plate 123. By virtue of being fastened to the multi-chip module 100, the bolster plate 123 provides an amount of structural stability to the portion of the multi-chip module 100 to which it is attached. In other words, by being attached to a circuit board of the multi-chip module 100, the bolster plate 123 structurally reinforces the portion of the multi-chip module 100 to which the bolster plate 123 is attached. The lack of structural stability that may be attributable to the aperture 126 is within acceptable limits. The bolster plate 123 also facilitates the attachment of the remaining data capture apparatus such as the interposer 129, the translator board 133, and other components as will be described.

The interposer 129 is electrically coupled to the pad array 106 on the multi-chip module 100. In particular, the interposer 129 is placed into the aperture 126 after the bolster plate 123 is affixed to the multi-chip module 100 and is mated up against the pad array 106. In this respect, the aperture 126 provides for the exposure of the pad array 106 on the multi-chip module 100 through the bolster plate 123 to provide access to the pad array 106. Thereafter, the translator board 133 is electrically coupled to the interposer 129. Specifically, an interconnect on the underside of the translator board 133 is mated against a corresponding interconnect of the interposer 129.

The interposer 129 comprises a multi-layer substrate with two sides. Each side includes a compressible interconnect that is compatible with either the pin array 106 or the interconnect on the corresponding side of the translator board 133. The compressible interconnects of the interposer 129 facilitate a good electrical connection between the pad array 106 and the interposer 129, and between the interposer 129 and the translator board 133. The compressible interconnects may employ, for example, a spring type design or may employ a conductive polymer as can be appreciated. The remaining side of the translator board 133 that does not contact the interposer 129 comprises a pin array that is compatible with a socket (not shown) on the underside of the logical analyzer interface 143.

When assembled, the springs 136 are fastened to the bolster plate 123 by way of the screws 139. The springs 136 compress the translator board 133 into the interposer 129, thereby holding the translator board 133 and the interposer 129 against the pad array 106 of the multi-chip module 100. The springs 136 are selected so as to be relatively stiff to provide a large force with a very small deflection. This is because the springs 136 must maintain the general position and exert the maximum amount of force with a small amount of movement. For example, in one embodiment, the desired amount of force needed to hold the translator board 133 and the interposer 129 against the pad array 106 is generated with approximately 5 to 10 one thousandths of an inch of movement. In this respect, the springs 136 are extremely rigid. However, it is understood that the above range is merely an example and that other ranges may be specified depending upon the tolerances associated with the mating of the electrical contacts of the pad array 106, the interposer 129, and the translator board 133 as can be appreciated.

By employing rigid springs 136 that have a small range of motion necessary to generate a needed amount of force to hold the translator board 133 and the interposer 129 against the pad array 106, the interposer 129 and the translator board 133 may be held against the pad array 106 in a manner such that there is no motion of such components due to the compression of the springs 136 beyond a given tolerance to ensure proper contact between all of the contacts of the pad array 106 and the interposer 129, and between the interposer 129 and the translator board 133.

In one embodiment, a total of two springs 136 are employed to compress the translator board 133 into the interposer 129 and correspondingly compress the interposer 129 into the pad array 106. The use of the two springs 136 provides a symmetrical force applied to two sides of the translator board 133 to provide for proper mating of all contacts. Alternatively, the springs 136 may be embodied in a single structure to accomplish this task. In one embodiment, the springs 136 comprise leaf springs. However, as an additional alternative, the springs 136 may comprise any spring that would facilitate generating the compressive force necessary to hold the translator board 133 and the interposer 129 against the pad array 106.

In addition, the logical analyzer interface 143 may be an “off the shelf” component in which the orientation of the socket (not shown) would require that the tabs 146 lie in a direction that obstructs the pin array 103 when the logical analyzer interface 143 was plugged into the pin array of the translator board 133. In this respect, the tabs 146 of the logical analyzer interface 143 may lie in a direction rotated 90 degrees with respect to the orientation shown in FIG. 2.

Consequently, in one embodiment, to make sure that the tabs 146 do not interfere with the pin array 103 in plugging into a given socket of a system board or other device, the translator board 133 is constructed so as to rotate the contacts by 90°. Specifically, the first electrical contacts on the first side of the translator board that come into contact with the interposer 129 are rotated by 90° with respect to the pins of the pin array on the second side of the translator board 133. Thus, the first electrical contacts on the first side of the translator board 133 are rotated by 90° with respect to the second electrical contacts on the second side of the translator board 133. Alternatively, the contacts on either side of the interposer 129 may be rotated 90° with respect to each other in this manner.

This results in the tabs 146 being perpendicular with the general orientation of the multi-chip module 100. Consequently, the tabs 146 do not interfere with plugging the pin array 103 into an appropriate socket for testing. In designing the translator board 133 to effect the 90° rotation, the electrical characteristics of the conductors in the translator board are designed to provide for the proper characteristic impedance and other electrical characteristics.

In addition, the bolster plate 123 also includes clips 153 that are fastened to the bolster plate 123 with screws 156. The clips 153 are employed to hold the edges of the logical analyzer interface 143 with respect to the bolster plate 123. In this manner, after the logical analyzer interface 143 has been plugged into the pin array on the translator board 133, then the clips 153 are put into place and the logical analyzer interface 143 is held down so that the connection between the pin array of the translator board 133 and the socket on the logical analyzer interface 143 is properly maintained.

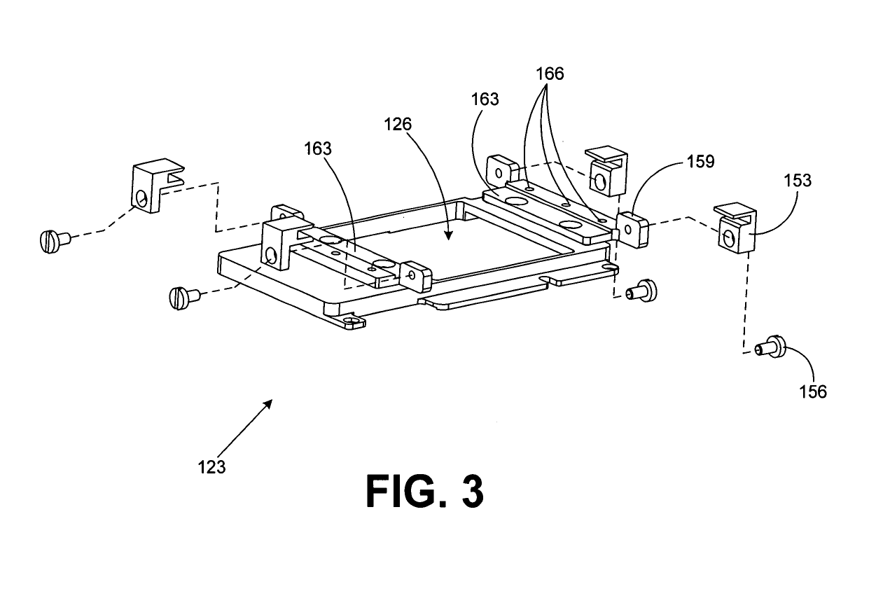

With reference to FIG. 3, shown is a view of the bolster plate 123 according to an embodiment of the present invention. The bolster plate 123 includes the aperture 126. Also, the bolster plate 123 includes the clips 153 that are fastened to the bolster plate 123 by way of the screws 156 in order to hold the logical analyzer interface 143 as described above. In addition, the bolster plate 123 includes ears 159 within which are threaded holes that receive the screws 156 to hold the clips 153 onto the bolster plate 123. In addition, in one embodiment, the bolster plate includes two decks 163 upon which holes 166 are drilled in order to facilitate the fastening of the springs 136 (FIG. 2) to the bolster plate 123. It is understood that there may be more or less decks 163 for the fastening of springs to the extent that alternative spring configurations are employed.

Referring back to FIG. 2, next, a method for coupling a logical analyzer to the multi-chip module 100 for data capture is described. In one embodiment, the method comprises the steps of attaching the bolster plate 123 with the aperture 126 to the multi-chip module 100 and exposing the pad array 106 on the multi-chip module 100 through the aperture 126. The method further comprises the steps of electrically coupling the interposer 129 to the pad array 106 and electrically coupling the translator board 133 to the interposer 129. Finally, the logical analyzer interface 143 is electrically coupled to the translator board 133. Specifically, a socket of the logical analyzer interface 143 is coupled to the pin array of the translator board 133.

Thereafter, a logical analyzer is coupled to the tabs 146 of the logical analyzer interface 143 and a process is run in conjunction with the multi-chip module 100 in order to capture an amount of data from the multi-chip module 100 during a test of the multi-chip module 100. The amount of data is captured through the interposer 129, the translator board 133, and the logical analyzer interface 143.

The method further comprises the step of applying an amount of force against the translator board 133 with at least one spring 136, thereby pressing the translator board 133 into the interposer 129, whereby the translator board 133 and the interposer 129 are held against the multi-chip module 100. Specifically, the translator board 133 and the interposer 129 are held against the pad array 106 on the bottom surface of the multi-chip module 100.

The method further comprises the step of fastening the one or more springs 136 to the bolster plate 123. Also, the method further comprises the step of rotating a plurality of first electrical contacts in a first side of the translator board 133 by 90° with respect to the plurality of second electrical contacts such as the pin array on the second side of the translator board 133. Alternatively, the contacts on either side of the interposer 129 may be rotated by 90° with respect to each other.

According to one embodiment, when the interposer 129 is compressed between the pad array 106 and the translator board 133, compressible interconnects on either side of the interposer 129 are compressed to ensure proper electrical contact. The compressible interconnects may be, for example, a spring type design or may employ a conductive polymer as can be appreciated. While the bolster plate 123 is attached to the multi-chip module 100, the instant method further comprises the step of structurally reinforcing at least a portion of the multi-chip module 100 with the bolster plate 123. Also, the instant method includes the step of fastening the logical analyzer interface 143 to the bolster plate 123 with a plurality of retaining clips 153.

Although the invention is shown and described with respect to certain embodiments, it is obvious that equivalents and modifications will occur to others skilled in the art upon the reading and understanding of the specification. The present invention includes all such equivalents and modifications, and is limited only by the scope of the claims.

What is claimed is:

1. A data capture assembly, comprising:
a bolster plate with an aperture attached to a multi-chip module, wherein a pad array on the multi-chip module is exposed through the aperture;
an interposer electrically coupled to the pad array on the multi-chip module;
a translator board electrically coupled to the interposer; and
a logical analyzer interface electrically coupled to the translator board.

2. The data capture assembly of claim 1, further comprising at least one spring compressing the translator board onto the interposer, thereby holding the translator board and the interposer against the multi-chip module.

3. The data capture assembly of claim 2, wherein the at least one spring is fastened to the bolster plate.

4. The data capture assembly of claim 1, wherein a plurality of first electrical contacts on a first side of the translator board are rotated by 90° with respect to a plurality of second electrical contacts on a second side of the translator board.

5. The data capture assembly of claim 1, wherein the interposer further comprises a substrate with two sides, wherein a compressible interconnect is disposed on each of the sides.

6. The data capture assembly of claim 1, wherein the bolster plate provides an amount of structural stability to a portion of the multi-chip module.

7. The data capture assembly of claim 1, further comprising a plurality of retaining clips fastening the logical analyzer interface to the bolster plate.

8. The data capture assembly of claim 1, further comprising a pin array disposed on a surface of the multi-chip module, wherein the pad array is also disposed on the surface of the multi-chip module.

9. The data capture assembly of claim 8, further comprising a socket extender disposed on the pin array.

10. The data capture assembly of claim 1, wherein the translation board includes a pin array that is compatible with a socket on the logical analyzer interface.

11. A method for coupling a logical analyzer to a multi-chip module for data capture, comprising the steps of:
attaching a bolster plate with an aperture to a multi-chip module;
exposing a pad array on the multi-chip module through the aperture;
electrically coupling an interposer to the pad array;
electrically coupling a translator board to the interposer;
electrically coupling a logical analyzer interface to the translator board; and
capturing an amount of data from the multi-chip module during a test of the multi-chip module through the interposer, the translator board, and the logical analyzer.

12. The method of claim 11, further comprising the step of applying an amount of force against the translator board with a spring, thereby pressing the translator board onto the interposer, whereby the translator board and the interposer are held against the multi-chip module.

13. The method of claim 12, further comprising the step of fastening the spring to the bolster plate.

14. The method of claim 11, further comprising the step of rotating a plurality of first electrical contacts on a first side of the translator board by 90° with respect to a plurality of second electrical contacts on a second side of the translator board.

15. The method of claim 11, further comprising compressing a compressible interconnect on each side of the interposer.

16. The method of claim 11, further comprising the step of structurally reinforcing at least a portion of the multi-chip module with the bolster plate.

17. The method of claim 11, further comprising the step of fastening the logical analyzer interface to the bolster plate with a plurality of retaining clips.

18. A data capture assembly, comprising:
bolster plate means for facilitating an attachment of a data capture apparatus to a multi-chip module and for structurally reinforcing at least a portion of the multi-chip module;
means for exposing a pad array on the multi-chip module through the bolster plate to provide access to the pad array;
an interposer electrically coupled to the pad array;
a translator board electrically coupled to the interposer;
means for pressing the interposer and the translator board against the pad array; and
a logical analyzer interface electrically coupled to the translator board.

19. The data capture assembly of claim 18, wherein the means for pressing the interposer and the translator board against the pad array further comprises at least one spring attached to the bolster plate means.

20. The data capture assembly of claim 18, wherein a plurality of first electrical contacts on a first side of the translator board are rotated by 90° with respect to a plurality of second electrical contacts on a second side of the translator board.
